(19) United States
(12) Patent Application Publication
(10) Pub. No.: US 2015/0282297 A1
(43) Pub. Date: Oct. 1, 2015

(54) Printed Circuit Board

(71) Applicant: Tyco Electronics AMP Korea Ltd., Gyungsangbuk-do (KR)

(72) Inventors: Yang Yun Choi, Gyungsangbuk-Do (KR); Ok Ky Beak, Gyeonggi-do (KR)

(73) Assignee: Tyco Electronics AMP Korea Ltd., Gyungsan-si (KR)

(21) Appl. No.: 14/730,720

(22) Filed: Jun. 4, 2015

Related U.S. Application Data
(63) Continuation of application No. PCT/KR2013/011249, filed on Dec. 6, 2013.

(30) Foreign Application Priority Data
Dec. 7, 2012 (KR) 10-2012-0141577

(51) Int. Cl. H05K 1/02; H05K 1/09

(52) U.S. Cl. CPC H05K 1/0213; H05K 1/092

(57) ABSTRACT

A printed circuit board has a substrate having a circuit pattern; a primary component receiving hole positioned on the substrate and having an inner surface electrically connected with the circuit pattern; and at least one secondary component receiving hole positioned on the substrate around the primary component receiving hole, and having an inner surface electrically connected with the circuit pattern and the inner surface of the primary component receiving hole.

### CROSS-REFERENCE TO RELATED APPLICATIONS

This application is a continuation of PCT International Application No. PCT/KR2013/011249 filed Dec. 6, 2013, which claims priority under 35 U.S.C. §119 to Korean Patent Application No. 10-2012-0141577 filed Dec. 7, 2012.

### FIELD OF THE INVENTION

The invention is generally related to a printed circuit board (PCB), and, more specifically, to a PCB having interference-fit device receiving holes.

### BACKGROUND

In general, a printed circuit board (PCB) is an electrical component in which electric wirings are integrated to allow various devices to be populated therein or to be electrically connected to one another. Demand for PCBs has been increasing for use in home appliances, communication devices, semiconductor equipment, industrial machinery, and electrical control of a vehicle. In addition, PCB products are being transformed into a miniaturized, light-weight, and high value-added products as electronic components become smaller and more sophisticated.

A predominant feature of electronic components mounted on a PCB is that as these electronic components perform complex functions, the electronics consume a considerable amount of power and generate a large amount of heat. Thus, a degree of heat generated from the various mounted electronic components may be a factor used to evaluate a degree of consumer satisfaction with the overall electronic product, and may be a factor affecting whether the consumer purchases the product.

A conventional PCB has one or more component receiving holes for mounting electronic components. The component receiving hole frequently becomes damaged due to an impact occurring when an electronic component is inserted into the component receiving hole or an impact occurring after an electronic component is mounted. In addition, such an impact may disconnect an electrical connection between the electronic components and the PCB.

Additionally, solderless mounting methods are often used to attach electrical components to the PCB in lieu of using existing soldering methods, often due to environmental regulations. Such solderless methods often include inserting a terminal or a pin into the component receiving hole formed on the PCB using a dimensional tolerance, known as an interference fit. While the interference fit permits the terminal or pin to be fixed to the PCB without the use of solder, often the insertion of the terminal results in scratches on a plated layer of an inner surface of the hole. These scratches can result in damage to the entire plating or a part of the plating of the inner surface of the hole. This damage is due to an overall dimension of the terminal and a tight tolerance of the component receiving hole, or due to poor plating on an inner surface of the component receiving hole. The damage often results in an electrical disconnection between electrically conductive layers of the PCB.

### SUMMARY

A printed circuit board has a substrate having a circuit pattern; a primary component receiving hole positioned on the substrate and having an inner surface electrically connected with the circuit pattern; and at least one secondary component receiving hole positioned on the substrate around the primary component receiving hole, and having an inner surface electrically connected with the circuit pattern and the inner surface of the primary component receiving hole.

### BRIEF DESCRIPTION OF DRAWINGS

The invention will be described by way of example, with reference to the accompanying Figures, of which:

FIG. 1 is a cross-sectional view of a printed circuit board having a secondary component receiving hole;

FIG. 2 is a cross-sectional view of a printed circuit board;

FIG. 3 is a cross-sectional view of a primary component receiving hole and a secondary component receiving hole of the printed circuit board of FIG. 1;

FIG. 4 is a plan view a terminal or a pin inserted in the primary component receiving hole of the printed circuit board of FIG. 1;

FIG. 5 is a plan view of the terminal or the pin is inserted in a primary component receiving hole; and

FIG. 6 is a plan view of a primary component receiving hole and a secondary component receiving hole.

### DETAILED DESCRIPTION OF THE EMBODIMENT(S)

Reference will now be made in detail to embodiments of the invention, examples of which are illustrated in the accompanying drawings, wherein like reference numerals refer to the like elements throughout. The embodiments are described below in order to explain the invention by referring to the figures. In descriptions of exemplary embodiments provided herein, known functions or configurations may be omitted for purposes of clarity and conciseness.

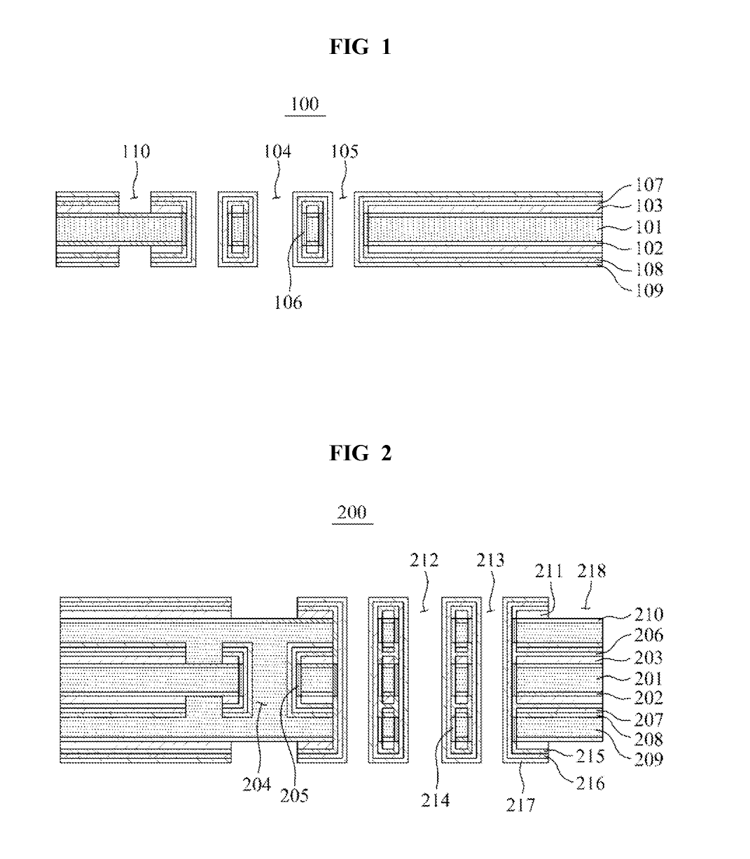

Hereinafter, a printed circuit board (PCB) on which a secondary component receiving hole is formed will be described in detail with reference to FIGS. 1 through 6. Unless indicated otherwise, a phrase “on a layer” may refer to “on both an upper surface and a lower surface of a layer.”

In an embodiment shown in FIG. 1, a PCB 100 includes a primary component receiving hole 104 into which an electrical component is inserted to be mounted on the PCB 100, and at least one secondary component receiving hole 105 positioned proximate to the primary component receiving hole 104. The primary component receiving hole 104 and the secondary component receiving hole 105 together form a single, enlarged component receiving hole.

The PCB 100 includes a base layer 103 of an aluminum material bonded on both surfaces of a core layer 101 using a bonding material 102. In an embodiment, a general copper-based substrate is used as the PCB 100. In another embodiment, a PCB of an aluminum material substrate is used as the PCB 100. For example, a metallic material including aluminum or an insulating material may be used for the core layer 101. The bonding material 102 may be a polyimide-based insulating bonding sheet having a desirable adhesion and an insulating function or an epoxy-based adhesive such as a glass epoxy resin. The bonding material 102 bonds to the base layer 103 of aluminum.

In the formation of the primary component receiving hole 104 and the secondary component receiving hole 105, a metal layer 106 is deposited on the inner surface of the primary component receiving hole 104 and the inner surface of the secondary component receiving hole 105 to cover any of the exposed insulting material of the core layer 101. For example, the metal layer 106 may form a carbon plating layer using a carbon direct plating method. With the formation of the metal layer 106, the base layer 103 formed on both surfaces of the core layer 101 is electrically connected.

In an embodiment, when the core layer 101 is made of the insulating material, the metal layer 106 is deposited on all surfaces of the core layer 101 and the bonding material 102 exposed to the inner surface of the primary component receiving hole 104 and the secondary component receiving hole 105. In an embodiment, when the core layer 101 is made of the metallic material, the metal layer 106 is deposited on a portion of the bonding material 102, which is exposed on the inner surface of the primary component receiving hole 104 and the secondary component receiving hole 105.

An oxidation prevention layer 107 is positioned on the base layer 103, being formed by substituting a zinc film for a portion of the aluminum on an outer surface of the base layer 103, based on a thickness of the metal layer 106. While the oxidation prevention layer 107 is not formed on the metal layer 106, the oxidation prevention layer 107 is formed identically in the primary component receiving hole 104 and the secondary component receiving hole 105. With the formation of the oxidation prevention layer 107, aluminum may be prevented from being oxidized in an atmosphere to protect the surface of the base layer 103. In addition, corrosion of the surface of the base layer 103 may be prevented in a process of electrolytic plating and electroless plating to be subsequently performed.

A first plating layer 108 is positioned on the oxidation prevention layer 107. The first plating layer 108 is formed through the electrolytic and the electroless plating performed on the oxidation prevention layer 107. Similarly, the first plating layer 108 is formed identically in the primary component receiving hole 104 and the secondary component receiving hole 105. The first plating layer 108 is formed by performing displacement plating on the oxidation prevention layer 107 using a metal film having a strong chemical resistance. For example, the first plating layer 108 is formed by performing the displacement plating using nickel (Ni) to substitute a nickel film for the oxidation prevention layer 107. However, the displacement plating is not limited to using nickel, and other metals having a strong chemical resistance, for example, gold (Au) and silver (Ag), may be used for the displacement plating. The first plating layer 108 covers an outer surface of the oxidation prevention layer 107, and also covers a portion or an entirety of the metal layer 106. In an embodiment, the first plating layer 108 is positioned only on the oxidation prevention layer 107, apart from the metal layer 106. A second plating layer 109 positioned on the first plating layer 108 using electro-copper plating, as well as identically in the primary component receiving hole 104 and the secondary component receiving hole 105.

To form a predetermined circuit pattern 110 on the second plating layer 109, a dry film is applied onto a surface of the second plating layer 109, and exposure and development are performed for a predetermined amount of time. Subsequent to the formation of the pattern 110, the second plating layer 109, the first plating layer 108, the oxidation prevention layer 107, and the base layer 103 are removed along the pattern of the dry film to form the PCB 100 in which the circuit pattern 110 is formed. The circuit pattern 110 is formed using hydrochloric acid-based acidic etching based on the pattern of the dry film. For example, a hydrochloric acid type may include ferric chloride, cupric chloride, and sodium chlorate.

A surface of the metal layer 106 is covered by at least one of the first plating layer 108 and the second plating layer 109. In an embodiment, when the first plating layer 108 does not cover the metal layer 106, the second plating layer 109 covers the outer surface of the metal layer 106. When the first plating layer 108 covers only a portion of the metal layer 106, the second plating layer 109 covers the first plating layer 108 and a portion of the metal layer 106 that is not covered by the first plating layer 108. When the first plating layer 108 fully covers the metal layer 106, the first plating layer 108 and the second plating layer 109 are positioned on the metal layer 106.

In an embodiment, since the metal layer 106, the oxidation prevention layer 107, the first plating layer 108, and the second plating layer 109 are formed identically in the primary component receiving hole 104 and the secondary component receiving hole 105, the inner surfaces of the primary component receiving hole 104 and the secondary component receiving hole 105 may have identical electrical configurations. The term “electrical configurations” indicates identical structural compositions, ordering, or shapes of the metal layer 106, the oxidation prevention layer 107, the first plating layer 108, and the second plating layer 109.

While an embodiment shown in FIG. 1 is a double-sided PCB 100, the PCB 100 is not limited to the double-sided PCB. Those of ordinary skill in the art would appreciate that the above embodiments may be similarly applied to a multilayer PCB 200, which is formed by layering at least two double-sided PCBs, to be described hereinafter. For example, as shown in an embodiment of FIG. 2, the multilayer PCB 200 may be used. Descriptions of the multilayer PCB 200 may be substantially similar to the descriptions of the double-sided PCB provided in the foregoing. Thus, components of the multilayer PCB 200 substantially similar to the components of the PCB 100 described with reference to FIG. 1 will be referred to using the same names of the components of the PCB 100, and repeated descriptions will be omitted here for brevity.

Referring to the embodiment shown in FIG. 2, the multilayer PCB 200 includes an insulating layer 209 of an insulating material to fill a circuit pattern on a PCB, including components 201 through 208, formed as described with reference to FIG. 1. A general copper-based substrate or an aluminum-based substrate may be used for the multilayer PCB 200. Alternatively, a metallic material, including aluminum, or an insulating material may be used for a core layer 201 of the multilayer PCB 200.

The insulating layer 209 fills both the circuit pattern and a through-hole 204. A base layer 211 of an aluminum material is positioned on and below the insulating layer 209. For example, an aluminum foil having a predetermined thickness may be used for the base layer 211. The base layer 211 and the insulating layer 209 are bonded together using a bonding material 210 such as the polyimide-based insulating bonding sheet or the epoxy-based adhesive discussed above with reference to FIG. 1.

Subsequent to the formation of the insulating layer 209, the bonding material 210, and the base layer 211, a primary component receiving hole 212 and a secondary component receiving hole 213 are formed to penetrate through the PCB 200, including the components 201 through 208, the insulating layer 209, the bonding material 210, and the base layer 211.

Subsequently, a metal layer 214, a oxidation prevention layer 215, a first plating layer 216, a second plating layer 217 are sequentially formed in the primary component receiving hole 212 and the secondary component receiving hole 213 to form both a predetermined circuit pattern 218 using a dry film and the multilayer PCB 200. The method of forming the metal layer 214, the oxidation prevention layer 215, the first plating layer 216, and the second plating layer 217 in the primary component receiving hole 212 and the secondary component receiving hole 213 are identical to the methods described with reference to FIG. 1 and thus, repeated descriptions will be omitted here for brevity.

Although a double-layered PCB is illustrated as the multilayer PCB 200, the multilayer PCB 200 is not limited to the double-layered PCB. Those of ordinary skill in the art would appreciate that a higher-layered PCB including three, four, five, or more layers may also be applicable as the multilayer PCB 200. Additionally, those of ordinary skill in the art would appreciate that the invention is not limited to the configuration of the PCB 100 described with reference to FIG. 1 and thus, various modifications may be made to the configurations of the PCB 100.

Hereinafter, the primary component receiving hole 104 and the secondary component receiving hole 105 will be further described with reference to FIGS. 3 through 6. For ease of description, descriptions to be provided hereinafter are applied to the configurations of the PCB 100 shown in the embodiment of FIG. 1. However, the invention is not limited thereto, and the descriptions to be provided hereinafter can also be applied to the multilayer PCB 200 shown in the embodiment in FIG. 2.

The primary component receiving hole 104 extends through the PCB 100 to allow an electrical component to be mounted on the PCB 100. In an embodiment (not shown), those of ordinary skill in the art would appreciate that the primary component receiving hole 104 can partially extend into the PCB 100 to a predetermined depth from a surface of the PCB 100.

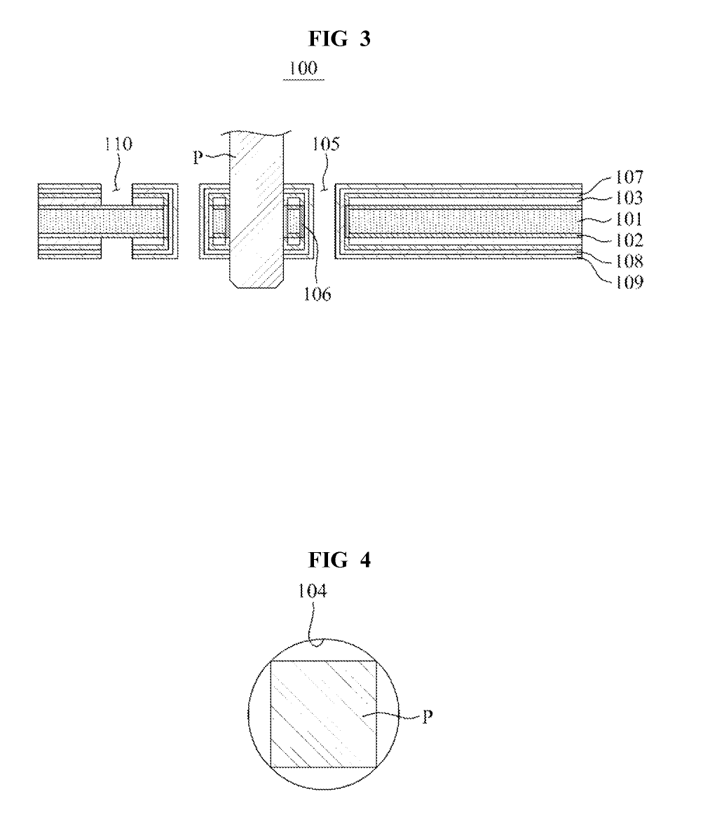

In the embodiments shown in FIGS. 3 and 4, a solderless type PCB 100, a terminal or a pin P is fixed in the primary component receiving hole 104 in a manner of interference fit. Conventionally, during insertion of the terminal or the pin P in the primary component receiving hole 104, the terminal or the pin P may be fixed and electrically conductive while scoring a plating layer of an inner surface of the primary component receiving hole 104. Here, a portion or an entirety of the layers formed in the primary component receiving hole 104 may be broken during the insertion of the terminal or the pin. However, such damage and electrical disconnection between the layers that may occur during the insertion of the terminal or the pin P may be prevented by the secondary component receiving hole 105.

The secondary component receiving hole 105 is positioned around the primary component receiving hole 104. In an embodiment, a single secondary component receiving hole 105 or a plurality of secondary component receiving holes 105 may be positioned separately from the primary component receiving hole 104 by a predetermined distance. When the primary component receiving hole 104 is damaged due to an impact occurring at a time of component insertion or an impact occurring after insertion of the component, the secondary component receiving hole 105 may prevent an electrical disconnection of a circuit and substitute for an electrical configuration of the primary component receiving hole 104.

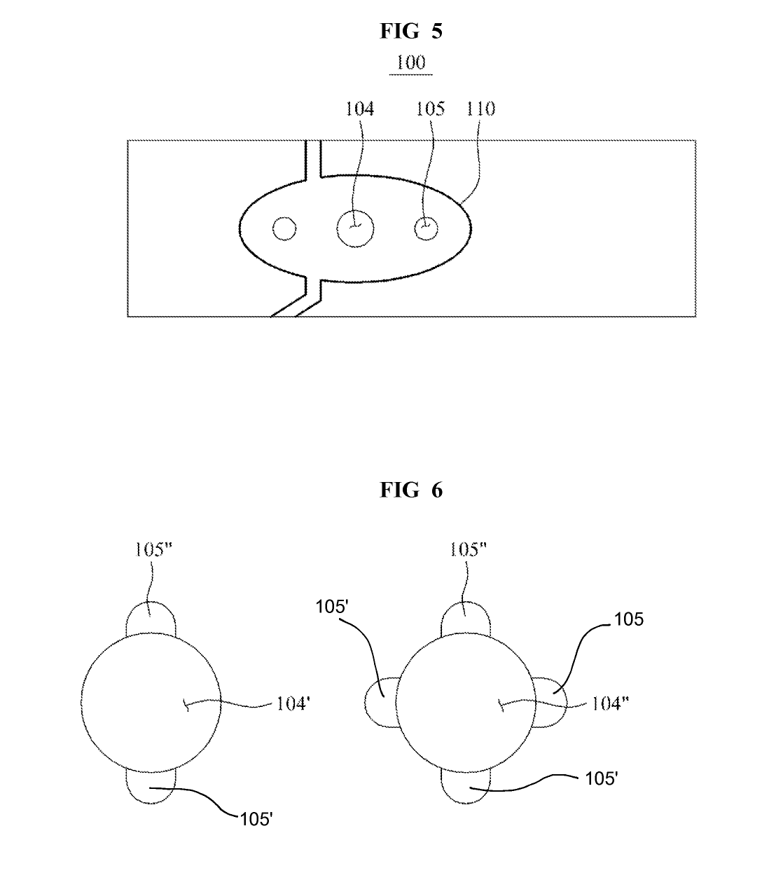

As shown in the embodiment of FIG. 5, the primary component receiving hole 104 and the secondary component receiving hole 105 are formed on the single circuit pattern 110 to have identical electrical configurations. Further, the primary component receiving hole 104 and the secondary component receiving hole 105 are positioned on a single pattern of the circuit pattern 110, with the electrical configurations of the conductive layers and insulating layers being identical in the primary component receiving hole 104 and the secondary component receiving hole 105. The dispositions of the layers in the primary component receiving hole 104 form a circuit and thus, the secondary component receiving hole 105 may allow a normal electrical operation to be performed in place of the primary component receiving hole 104 when the primary component receiving hole 104 is damaged.

The primary component receiving hole 104 and the secondary component receiving hole 105 are formed by performing drilling or laser processing on the PCB 100. Although cross-sectional forms of the primary component receiving hole 104 and the secondary component receiving hole 105 are shown in the Figures as being in circular, the shape is not limited to this. In other embodiments, the cross-sectional forms of the primary component receiving hole 104 and the secondary component receiving hole 105 may be an elliptical or polygonal, square, triangular, or the like. In addition, although the secondary component receiving hole 105 is shown to be smaller than the primary component receiving hole 104, the sizes of the primary component receiving hole 104 and the secondary component receiving hole 105 is merely exemplary, and in other embodiments, the cross-sectional areas of the primary component receiving hole 104 and the secondary component receiving hole 105 may be equal to each other.

Further, although two secondary component receiving holes are shown in the Figures as the secondary component receiving hole 105, the number of the secondary component receiving holes 105 is not to be limited thereto, and the number and a position of the secondary component receiving hole 105 may vary.

For example, the primary component receiving hole 104 and the secondary component receiving hole 105 may not be separate from each other, and may be connected. As shown in an embodiment of FIG. 6, a secondary component receiving hole 105′ and a secondary component receiving hole 105″ are positioned around a primary component receiving hole 104′ and a primary component receiving hole 104″ to be connected to the primary component receiving hole 104′ and the primary component receiving hole 104″. A plurality of the secondary component receiving holes 105′ and 105″ may be disposed at equidistant intervals or irregular intervals.

With the primary component receiving holes 104′ and 104″ and the secondary component receiving holes 105′ and 105″ being electrically connected to one other, the secondary component receiving holes 105′ and 105″ may substitute for electrical characteristics of the primary component receiving holes 104′ and 104″. Such a formation may function as a heat sink to allow heat to readily radiate through the primary component receiving holes 104′ and 104″ and the secondary component receiving holes 105′ and 105″.

Although a single primary component receiving hole 104 is shown to be electrically connected to a plurality of secondary component receiving holes 105, such as in the embodiment shown in FIG. 5, the invention is not limited to such a form, and in other embodiments, a plurality of primary component receiving holes 104 may be connected to a plurality of secondary component receiving holes 105. In addition, sizes and forms of the primary component receiving hole 104 and the secondary component receiving hole 105 may be variously modified.

A PCB manufactured in accordance with example embodiments described herein may be applicable to an electronic component for a vehicle.

When damage to a primary component receiving hole 105 or an electrical disconnection occurs due to an impact occurring at a time of inserting a component to be mounted on the PCB 100 or after mounting the component on the PCB 100, the secondary component receiving hole 105 may substitute for the primary component receiving hole 104 to prevent occurrence of damage and faultiness. In addition, since the secondary component receiving hole 105 is positioned around the primary component receiving hole 104, heat generated from an electronic component inserted in the primary component receiving hole 104 may be effectively released. While this disclosure includes specific examples, those of ordinary skill in the art would appreciate that various changes in form and details may be made the various embodiments without departing from the spirit and scope of the claims and their equivalents. The embodiments described herein are exemplary, and are not for purposes of limitation. Descriptions of features or aspects in each embodiment are to be considered as being applicable to similar features or aspects in other embodiments. Suitable results may be achieved if the described techniques are performed in a different order, and/or if components in a described system, architecture, device, or circuit are combined in a different manner and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. A printed circuit board, comprising:
a substrate having a circuit pattern;
a primary component receiving hole positioned on the substrate and having an inner surface electrically connected with the circuit pattern; and
at least one secondary component receiving hole positioned on the substrate around the primary component receiving hole, and having an inner surface electrically connected with the circuit pattern and the inner surface of the primary component receiving hole.

2. The printed circuit board of claim 1, wherein the secondary component receiving hole has a cross-sectional area smaller than or equal to a cross-sectional area of the primary component receiving hole.

3. The printed circuit board of claim 1, wherein a cross-sectional shape of the primary component receiving hole is circular, elliptical, polygonal, square, or triangular.

4. The printed circuit board of claim 1, wherein a cross-sectional shape of the secondary component receiving hole is circular, elliptical, polygonal, square, or triangular.

5. The printed circuit board of claim 1, wherein the primary component receiving hole and the secondary component receiving hole penetrate the substrate, and the inner surface of the primary component receiving hole and the inner surface of the secondary component receiving hole have identical electrical configurations.

6. The printed circuit board of claim 1, wherein the substrate includes
a core layer having two opposite surfaces;
a bonding material disposed on the two opposite surface of the core layer;
a base layer made of an aluminum material, and bonded to each of the opposite surfaces of the core layer through the bonding material.

7. The printed circuit board of claim 6, wherein the primary component receiving hole and the secondary component receiving hole each extend through the core layer, the bonding material, and the base layer.

8. The printed circuit board of claim 7, wherein the substrate further includes a zinc-based oxidation prevention layer positioned on an outer surface of the base layer and on a portion of the base layer exposed on the inner surface of the primary component receiving hole and the inner surface of the secondary component receiving hole.

9. The printed circuit board of claim 8, wherein the substrate further includes:
a plating layer positioned on the oxidation prevention layer; and
a circuit pattern positioned on the plating layer.

10. The printed circuit board of claim 9, wherein the core layer is a metallic material having aluminum or copper.

11. The printed circuit board of claim 9, wherein the core layer is an insulating material.

12. The printed circuit board of claim 11, wherein a portion of the core layer is exposed on the inner surface of the primary component receiving hole and the inner surface of the secondary component receiving hole.

13. The printed circuit board of claim 12, wherein a metal layer is positioned on the portion of the core layer exposed on the inner surface of the primary component receiving hole and the inner surface of the secondary component receiving hole.

14. The printed circuit board of claim 13, wherein the oxidation prevention layer is positioned on a remaining portion of the inner surface of the primary component receiving hole and the inner surface of the secondary component receiving hole away from the portion of the core layer exposed on the inner surfaces.

15. The printed circuit board of claim 14, wherein the plating layer is positioned on both the oxidation prevention layer and the metal layer.

16. The printed circuit board of claim 14, wherein the oxidation prevention layer has a thickness equal to a thickness of the metal layer.

17. The printed circuit board of claim 14, wherein the plating layer includes:
a first plating layer positioned on an outer surface of the oxidation prevention layer; and
a second plating layer made of a cupric material, and being positioned on the first plating layer.

18. The printed circuit board of claim 17, wherein the first plating layer is positioned on the oxidation prevention layer away from the metal layer, or positioned on both the oxidation prevention layer and a portion of the metal layer.

19. The printed circuit board of claim 18, wherein the second plating layer positioned on a portion of the metal layer away from the first plating layer.

20. The printed circuit board of claim 6, wherein the substrate is a layered substrate formed by layering the core layer, the base layer, and the bonding material at least twice.

21. The printed circuit board of claim 20, wherein the primary component receiving hole and the secondary component receiving hole penetrate the layered substrate.

22. The printed circuit board of claim 21, the substrate further comprises:
a zinc-based oxidation prevention layer positioned on an outer surface of the base layer and on a portion of the base layer exposed on the inner surface of the primary component receiving hole and the inner surface of the secondary component receiving hole;
a plating layer positioned on the oxidation prevention layer; and
a circuit pattern positioned on the plating layer.

23. The printed circuit board of claim 22, further comprising:
a metal layer is positioned on the portion of the core layer exposed on the inner surface of the primary component receiving hole and the inner surface of the secondary component receiving hole; and
the oxidation prevention layer is positioned on a remaining portion of the inner surface of the primary component receiving hole and the inner surface of the secondary component receiving hole away from the portion of the core layer exposed on the inner surfaces.
